(19) United States
(12) Patent Application Publication
(10) Pub. No.: US 2025/0067813 A1
(43) Pub. Date: Feb. 27, 2025

(54) SOURCE MEASURE UNIT

(71) Applicant: Keithley Instruments, LLC, Solon, OH (US)

(72) Inventors: Mark D. Zimmerman, Twinsburg, OH (US); Benjamin J. Yurick, Garrettsville, OH (US)

(73) Assignee: Keithley Instruments, LLC, Solon, OH (US)

(21) Appl. No.: 18/943,002

(22) Filed: Nov. 11, 2024

Related U.S. Application Data
(63) Continuation-in-part of application No. 18/159,729, filed on Jan. 26, 2023.
(60) Provisional application No. 63/606,452, filed on Dec. 5, 2023.
(60) Provisional application No. 63/306,924, filed on Feb. 4, 2022.

(51) Int. Cl. G01R 31/40; H02J 4/00

(52) U.S. Cl. CPC G01R 31/40; H02J 4/00

(57) ABSTRACT

In some examples, the system includes a primary power domain having: a first ground; a first set of measurement devices coupled to the first ground and configured to be powered by at least one of a first set of power supplies; and a second set of measurement devices coupled to the first ground and configured to be powered by at least one of the first set of power supplies. In addition, the system includes at least two isolated secondary power domains coupled to the primary power domain, each having: a second ground different from the first ground; a transformer coupled to the primary power domain, to a second set of power supplies, and to the second ground; and a third set of measurement devices coupled to the second ground and configured to be powered by at least one of the second set of power supplies.

### CROSS-REFERENCE TO RELATED APPLICATION

This application is a continuation-in-part of U.S. Nonprovisional application Ser. No. 18/159,729, titled “HIGH-DENSITY MULTI-CHANNEL POWER SUPPLY IN A TEST AND MEASUREMENT INSTRUMENT”, filed on Jan. 26, 2023, which in turn claims benefit of U.S. Provisional Application No. 63/306,924, titled “HIGH-DENSITY MULTI-CHANNEL POWER SUPPLY IN A TEST AND MEASUREMENT INSTRUMENT,” filed on Feb. 4, 2022. This application also claims benefit of U.S. Provisional Application No. 63/606,452, titled “SOURCE MEASURE UNIT,” filed on Dec. 5, 2023. The disclosures of each of these applications are incorporated herein by reference in their entirety.

### TECHNICAL FIELD

This disclosure relates to test and measurement instruments, and more particularly to a power supply subsystem for a test and measurement instrument.

### BACKGROUND

Multi-channel product designs that require high density, channel count and/or volume, have substantial challenges to the power supply subsystem if they require individual channel supplies. Source Measure Units (SMU), for example, require individual isolated power supplies with outputs independent from each other. A further challenge arises because typically a portion of the hardware circuits reference to a customer output, meaning that the output ground does not reference to Earth ground. The output grounds are galvanically isolated from Earth ground and are typically referred to as “floating.”

For an N-channel system, a challenge arises in providing N isolated supplies with space efficiency in a high-density design. Magnetic components for power supplies can easily make up the largest components in the design. For bipolar, analog SMU designs, this issue becomes exacerbated by requiring split winding or center tap (CT) winding transformer designs. Common solutions involve custom designed magnetic components. These solutions either do not scale or make achieving small sizes extremely difficult.

### SUMMARY

A system of one or more computers can be configured to perform particular operations or actions by virtue of having software, firmware, hardware, or a combination of them installed on the system that in operation causes or cause the system to perform the actions. One or more computer programs can be configured to perform particular operations or actions by virtue of including instructions that, when executed by data processing apparatus, cause the apparatus to perform the actions.

In one example, a system may include a primary power domain having: a first set of power supplies; a first ground; a first set of measurement devices coupled to the first ground and is configured to be powered by at least one of the first set of power supplies; and a second set of measurement devices coupled to the first ground and is configured to be powered by at least one of the first set of power supplies. The system may also include at least two isolated secondary power domains, each coupled to the primary power domain, each of the at least two isolated secondary power domains having: a second set of power supplies; a second ground different from the first ground; a transformer coupled to the primary power domain, to the second set of power supplies, and to the second ground; and a third set of measurement devices coupled to the second ground and are configured to be powered by at least one of the second set of power supplies. The system may furthermore include where the first set of measurement devices is associated with a first of the at least two isolated secondary power domains and the second set of measurement devices is associated to a second of the at least two isolated secondary power domains. Other examples include corresponding computer systems, apparatus, and computer programs recorded on one or more computer storage devices, each configured to perform the actions of the methods.

In one example, the system may include a first circuit having: a first set of power supplies; a first ground; a first set of measurement devices coupled to the first ground and is configured to be powered by at least one of the first set of power supplies; and a second set of measurement devices coupled to the first ground and is configured to be powered by at least one of the first set of power supplies. The system may also include a second and third isolated circuit, each coupled to the first circuit, each of the second and third isolated circuits having: a second set of power supplies; a second ground different from the first ground; a transformer coupled to the first circuit, the second set of power supplies, and the second ground; and a third set of measurement devices coupled to the second ground and are configured to be powered by at least one of the second set of power supplies. The system may furthermore include where the first set of measurement devices is associated with the second isolated circuit and the second set of measurement devices is associated to the third isolated circuit. Other examples include corresponding computer systems, apparatus, and computer programs recorded on one or more computer storage devices, each configured to perform the actions of the methods.

### BRIEF DESCRIPTION OF THE DRAWINGS

FIG. 1 shows an example of a test and measurement device having a multi-channel power supply block with isolated floating circuits.

FIG. 2 shows an embodiment of a multi-channel floating power supply block.

FIG. 3 shows a block diagram of a driver block.

FIG. 4 shows a display of non-overlapping driver waveforms.

FIG. 5 shows a circuit diagram of an embodiment of a driver block.

FIG. 6 is a diagram showing a system architecture with two isolated power domains, according to some examples.

FIG. 7 is a diagram showing a system architecture with multiple channels, each channel having its own isolated power domain, according to some examples.

FIG. 8 is a diagram showing a system architecture having a primary power domain and multiple secondary power domains, according to some examples.

FIG. 9 is a diagram showing a system architecture having a primary power domain and multiple secondary power domains, according to some examples.

### DETAILED DESCRIPTION

Embodiments here involve a power supply block. As used herein, the term “power supply block” means a power supply section or portion that provides multiple isolated channels in a small space, to differentiate the presently described power supply block from what may be considered conventional commercial power supplies available in the test and measurement equipment market. A power supply in the test and measurement market may employ one or more power supply blocks of the embodiments, as could other test and measurement equipment such as source measurement units (SMU), oscilloscopes, digital multimeters, etc. No limitation to any particular type of test and measurement equipment is intended. The below discussions use an example of an SMU, but only for ease of understanding the embodiments.

The power supply block described herein uses an interface magnetic component to provide multiple isolated transformers capable of providing multiple isolated power channels in the power supply block of the embodiments. A single power supply block may use more than one interface magnetics component to provide multiple channels, or the power supply block may be repeated as needed to provide a desired number of isolated power channels. The interface magnetic component comprises a number of transformers encapsulated in an integrated circuit component, which allows the resulting power supplies to achieve the desired high density while maintaining isolation, not otherwise obtainable using current methods.

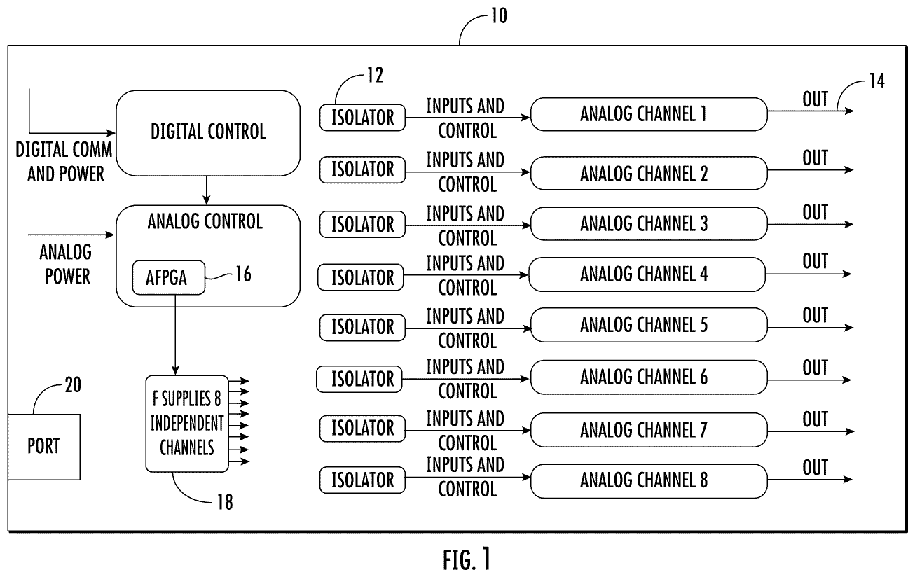

As mentioned above, the discussion uses a test and measurement device, such as an SMU, as an example of equipment into which the power supply block of the embodiments may be incorporated. FIG. 1 shows a test and measurement device 10, in this case an SMU, having a power supply block with eight independent channels with floating sections requiring eight independent power supplies. FIG. 1 shows the circuits that need isolation. These circuits that need isolation include the isolators 12, the outputs 14 of the channels, and the common driver 18. These isolated circuits require relatively low power to operate. As mentioned previously, the term “floating” means that the channels connect to a ground provided by the customer/user and have galvanic isolation from Earth ground.

The digital control circuitry receives digital communications, usually in the form of control signals, and digital power through a connector. The analog control circuitry receives analog power from an analog connector. The analog control circuitry includes a field programmable gate array (FPGA) 16 that produces the drive signals used to produce the signals for the 8 independent channels. This also provides signals used in the current embodiments. The test and measurement device 10 includes a port 20 or other connectors that allows the test and measurement device 10 to connect to a device under test. The test and measurement device 10 may include other circuit elements, such as analog-to-digital converters (ADC), user interface controls such as buttons and knobs, a display, and one or more processors. The test and measurement device 10 may comprise an SMU or other source, a digital multimeter, an oscilloscope, an analyzer, a signal generator, just as examples.

Current solutions include the use of individual transformer components. In a high density design, these transformer components strive to take up as little physically space as possible. For example, a first device has a size of 13.34 mm, and a second device having a size of 13 mm. Table 1 shows a comparison of these components, the estimated routing area resulting from them, and the area for using the component in an exemplary 8-channel solution. One should note that the examples here often refer to an 8-channel solution, but no limitation is intended to this particular example, nor should any be implied.

Another option would use a custom, multi-output, compact transformer, just as a typical example. One example has a size of 12.7×12.5 mm. Some designers may fashion a custom magnetics design to contain multiple output windings to accommodate the separate individual channels. A custom magnetics design can provide relatively compact solution for smaller channel counts but becomes quickly non-viable as the number of required channels increases. Table 1 shows a comparison of estimated sizes of an eight channel solution is shown for the above solutions.

TABLE 1
Implementation size estimates of traditional solutions

| Supported # | Component | Estimated Routing | Area for 8 CH |
|---|---|---|---|
| Channels (ea) | Area (mm) | Area (mm²) | Solution (mm²) |
| 1 (20) | 11 × 13.34 | 130 | 2214 |
| 2 (22) | 13 × 13 | 160 | 1316 |
| 2 (24) | 12.7 × 12.5 | 160 | 1275 |

Provided that the power levels needed have compatibility with the design requirements, one can repurpose a digital interface magnetic component for use in multi-channel power supply applications. The use of this digital interface magnetic component achieves an extraordinary reduction in the implementation of eight isolated channels. One example of this type of component has eight windings and is roughly 28×16 mm. The area for an 8-channel design comprises is 714 mm², a substantial space savings over the other designs shown in Table 1 that have footprints of well over 1000 mm², while this design is well under 1000 mm².

In one example, the communications link typically has two ends, a terminal equipment (TE) end that receives local alternating current (AC) power. The TE integrated circuit card connects to the secondary windings of the digital interface magnetic component and the primary windings are connected to the primary windings at the other end, network termination (NT) end. The NT circuit card connects to the the secondary windings connected to the NT circuit card.

Returning to FIG. 1, this digital interface magnetic component takes the place of the common channel driver 18. As discussed in more detail further, the digital interface magnetic component may have a custom driver circuit.

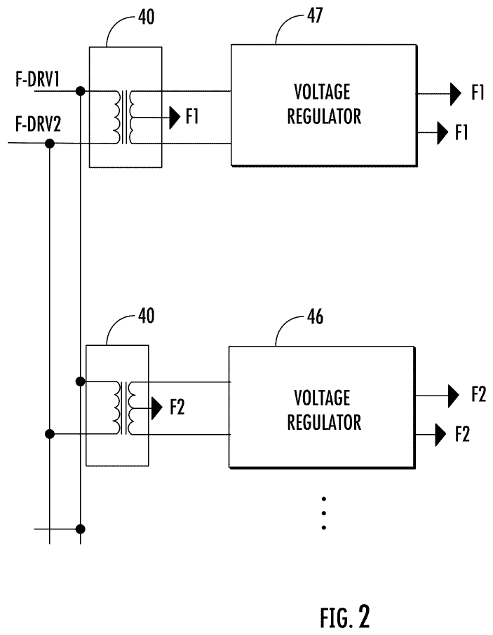

FIG. 2 shows embodiments of channels in a multi-channel power supply block such as usable in an SMU or other test equipment. FIG. 2 shows two channels, each employing one winding from a respective interface magnetic component 40, with the understanding that the channels replicate as many times as needed. The top circuit in the diagram may be for channel 1, the bottom circuit may be channel 2, etc. These channels as shown in FIG. 2 can be replicated as many times as needed for however many channels and the separation between the two windings of the interface magnetic component 40 is much smaller than shown. The same interface magnetic component 40 includes all the windings within the small footprint but is shown in two different locations for ease of understanding. As mentioned above, the power supply block itself may be repeated, and the power supply block may include more than one 8-transformer magnetic interface component, or use a magnetic interface component having more than 8 transformers, among other scenarios.

Each channel has several portions, each with a particular purpose.

In FIG. 2, the lower channel operates on one winding from the interface magnetic component 40. The winding of the interface magnetic component 40, in this case the CT, connects to a full bridge rectifier (not illustrated) that converts the AC power from the winding of the interface magnetic component 40 to direct current (DC) power. A smoothing circuit (not illustrated) smooths out the output of the rectifier to provide a smoother DC signal. A voltage regulator 46 regulates the DC power from the smoothing circuit to provide DC output signals of both positive and negative polarities. The voltage regulator 46 may include voltage regulating integrated circuits, a resistor-capacitor network that sets the voltage value and provides further voltage regulation, and a fixed regulator with no ability to set the voltage, but provides output positive and negative voltages at the F2 output terminals. The smoothing circuit and a fixed regulator are merely some optional circuits that may be included in the voltage regulator 46. These channel components are replicated for the first channel, including a full-bridge rectifier (not illustrated), a smoothing circuit (not illustrated), and voltage regulator 47, producing positive and negative output power signals F1.

As can be seen in the far left of FIG. 2, the interface magnetic component 40 is coupled to receive two input signals, F-DRV1 and F-DRV2. These input signals may result from a driving circuit.

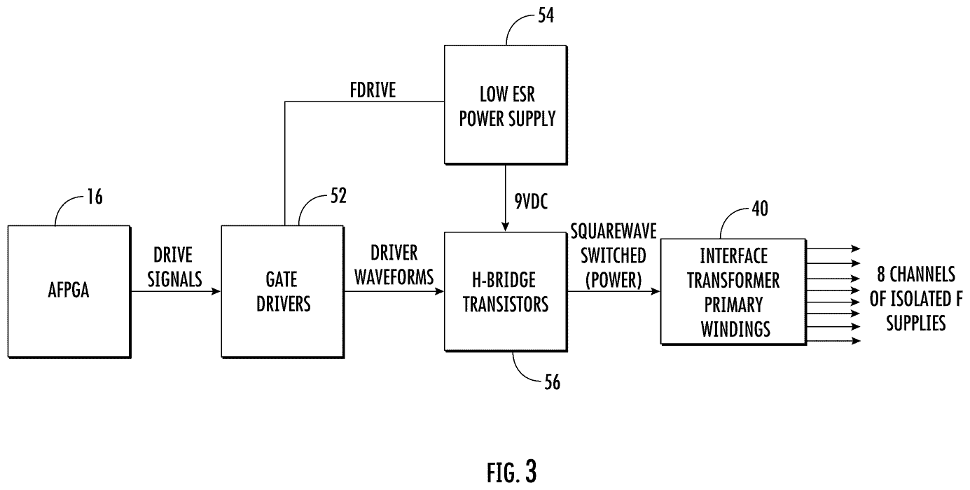

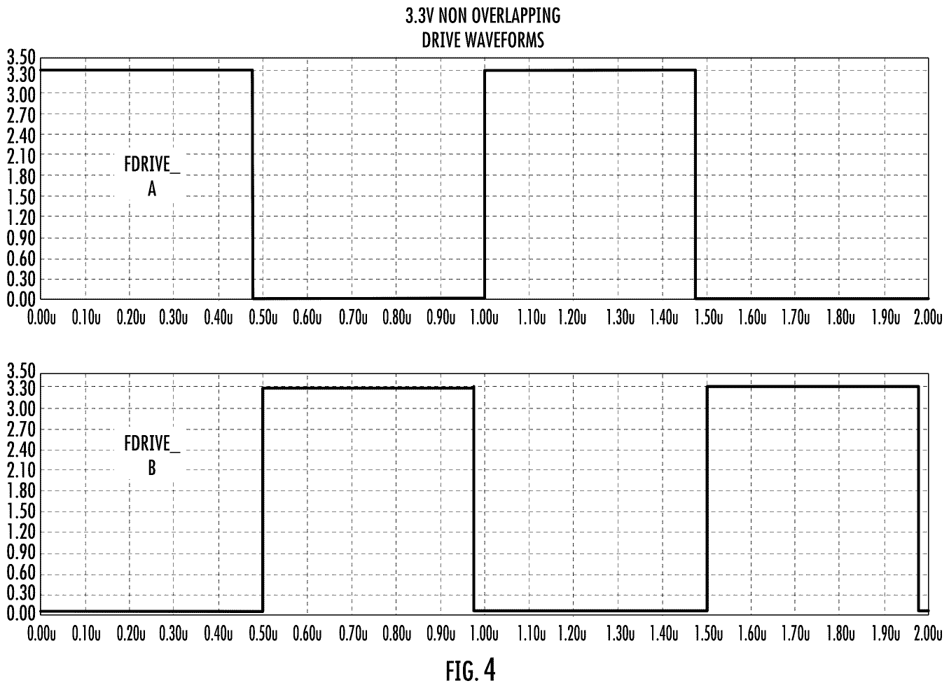

FIG. 3 shows an overall diagram for the context of the driving circuit. As illustrated, the FPGA 16 provides the drive signals to gate drivers 52 of FIG. 3. In one embodiment, the FPGA 16 supplies drive signals, FDRIVE_A and FDRIVE_B to the gate drivers 52. A low equivalent series resistance (ESR) power supply 54 provides a DC voltage to the H-bridge transistors 56. Upon receiving a DC voltage from the power supply 54, the H-bridge 56 produces the two driving signals F-DRV1 and F-DRV2 signals used by the windings in the interface magnetic component 40 to produce however many isolated channels of power are available in the interface magnetic componet 40. FIG. 4 shows an example of these driving signals FDRIVE_A and FDRIVE_B. In one embodiment, the driving signals are 3.3 V non-overlapping drive waveforms. Generally, the power supply block is considered low power, consuming less than 2 W, or in some cases less than 5 W.

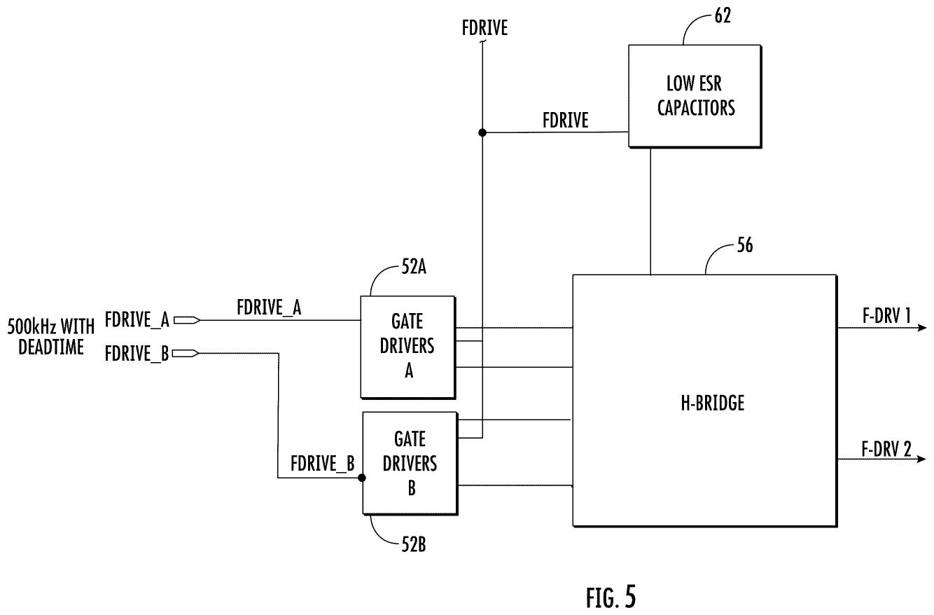

FIG. 5 shows an embodiment of a high frequency driver developed to operate to drive this digital interface magnetic component. In one embodiment, the frequency is at least 1 MHz. This driver delivers the power levels and voltage rails required. In one embodiment, the power levels and voltage rails are for all of the 8 isolated channels in a multi-channel SMU application. Without the driver, it would be quite difficult to reproduce the equivalent of such a compact arrangement with commonly available resources to original equipment manufacturers (OEMs). Moreover, the packaging in a compact standard integrated circuit footprint allows the normal usage of automated assembly equipment to place this digital interface magnetic component onto a printed circuit board (PCB) using known techniques.

In FIG. 5 the driver circuit receives the FDRIVE_A and FDRIVE_B signals from the FPGA 16, and the FDRIVE_A and FDRIVE_B signals act as inputs to the gate drivers 52A and 52B. The low ESR power supply 54 provides a DC power FDRIVE to the H-bridge 56. The bulk low ESR capacitance 62 acts on the DC power FDRIVE to feed current to the high speed switching converter in the H-bridge 56. In one embodiment, the H-bridge 56 comprises a set of four switching transistors in an H-bridge configuration having a dual arrangement. The H-bridge 56 may contain other components, such as RC components that slow the switching speed to reduce the electrical noise. The outputs from the H-bridge 56 comprise the F-DRV1 and F-DRV2 inputs to the digital interface magnetic components 40 of FIG. 2.

In this manner, a off the shelf, small footprint, component used in the telecommunications industry can be repurposed to provide isolated power signals to a multi-channel SMU. The embodiments include a driver that allows the digital interface magnetic component to be able to function correctly in the SMU environment.

In some examples, split supplies are needed for the use of miniaturized transformers to save space and cost inside a test and measurement device, such as an SMU. The present disclosure describes a system architecture with multiple isolated power domains. In some examples, the system architecture with multiple isolated power domains supports the multiple channels shown in FIG. 1.

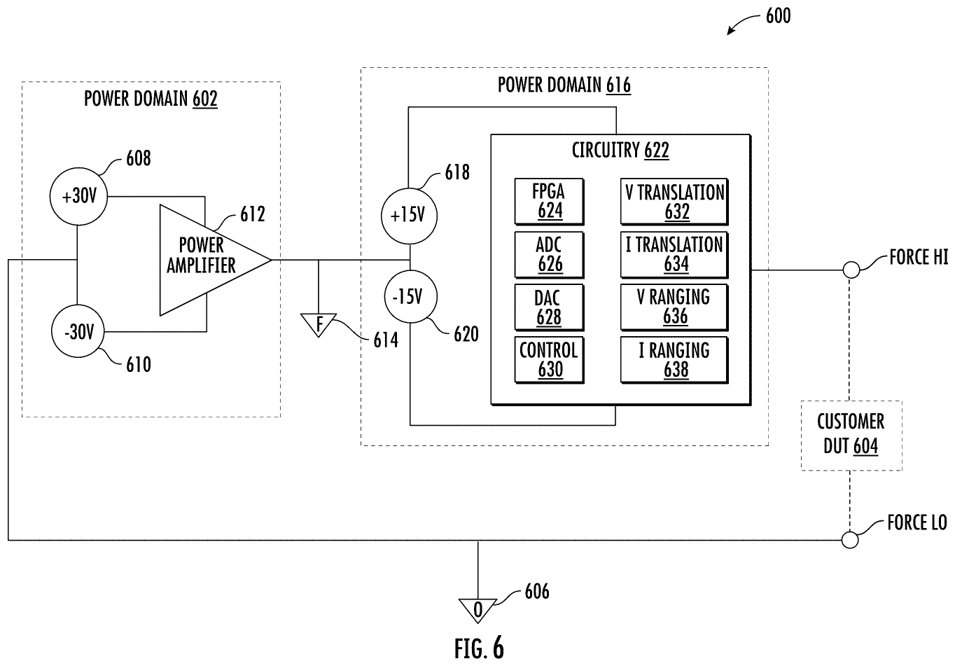

FIG. 6 is a diagram showing a system architecture with two power domains. As illustrated, the system 600 of FIG. 6 includes a first power domain 602 and a second power domain 616. The first power domain 602 is coupled to the second power domain 616. In some examples, the first power domain 602 provides a different amount of power to the components coupled to the first power domain 602 compared to the amount of power provided to components coupled to the second power domain 616. For example, the first power domain 602 provides 30 W to components coupled to the first power domain 602, while the second power domain 616 provides about 5 W to components of the second power domain 616. As illustrated, the first power domain 602 includes power supplies 608, 610 and a power amplifier 612. Similarly, the second power domain 616 includes power supplies 618, 620 and other circuitry 622. The output of the second power domain 616 is coupled to output Force HI. Similarly, the first power domain 602 is coupled to output Force LO. Correspondingly, the system 600 is set up so that a device under test (DUT) 604 can be coupled between outputs Force HI and Force LO.

In some examples, the first power domain 602, also referred to as “O” (or OGND) domain, has its ground 606 at Force LO, and the power supplies 608, 610 for the output stage sit on this ground 606. The system's output current flows from the power supplies 608, 610 of the first power domain 602, through the power amplifier 612 of the first power domain 602, and out to the DUT 604, returning on Force LO. The voltages on the power supplies 608, 610 need to be high enough to supply the maximum output range of the system 600. These power supplies 608, 610 need to be capable of driving the total output power of the system 600 in addition to overhead consumed internally. For example, the power supplies 608, 610 of the first power domain 602 are capable of driving 30 W of total output power. In some examples, the voltage of the power supplies 608, 610 is different from the voltage of the power supplies 618, 620. In such examples, the voltage of the power supplies 608, 610 is greater than from the voltage of the power supplies 618, 620. In some examples, the ground 606 is a floating ground relative to Earth ground or to a ground provided by a user.

As mentioned, the first power domain 602 is coupled to the second power domain 616, also referred to as “F” (or FGND) domain. The second power domain 616 has its ground 614 driven by the power amplifier 612 of the first power domain 602 and has lower voltage supplies 618, 620 that supply the circuitry 622 of the second power domain 616. In some examples, the circuitry 622 of the second power domain 616 includes low-voltage analog and digital circuitry, which includes but is not limited to, a floating FPGA 624, analog-to-digital converters (ADCs) 626, digital-to-analog converters (DACs) 628, control circuitry 630, voltage translation circuit 632, current translation circuit 634, voltage ranging circuit 636, and current ranging circuit 638. The other circuitry 622 can further include voltage sensors (not illustrated), current sensors (not illustrated), and other voltage and current measurement circuits. In some examples, the ground 614 is a floating ground relative to ground 606, Earth ground or to a ground provided by a user.

The benefit of situating this circuitry 622 with the second power domain 616 coupled to ground 614 as opposed to with the first power domain 602 coupled to ground 606 is threefold. Firstly, situating the measurement and control circuitry on the same ground as the sense circuitry eliminates common-mode error from difference between Force HI and Force LO. Secondly, at maximum output voltage, the floating supplies 618, 620 can be higher than the power supplies 608, 610 (also referred herein as the high-power rails, allowing for bias and control without having to extend the high-power rails to an even higher voltage. For example, if the power amplifier 612 can drive its output fully, then the power supply 618 on F can be 30 V+15 V=45 V above O ground 606. If a single O grounded supply 606 were to be used, it would need to be +/−45 V to cover the same range, where it only needs to be 30 V in this case. Thirdly, the system 600 as described herein allows for current ranging circuit 638 to be located on Force HI, thus providing the customer a “true” low-impedance ground node at Force LO.

However, the two power domains 602, 616 shown in FIG. 6 each require an isolated power supply, meaning isolated windings on a transformer or separate dedicated transformers. These transformers are large, expensive, and often custom-ordered components.

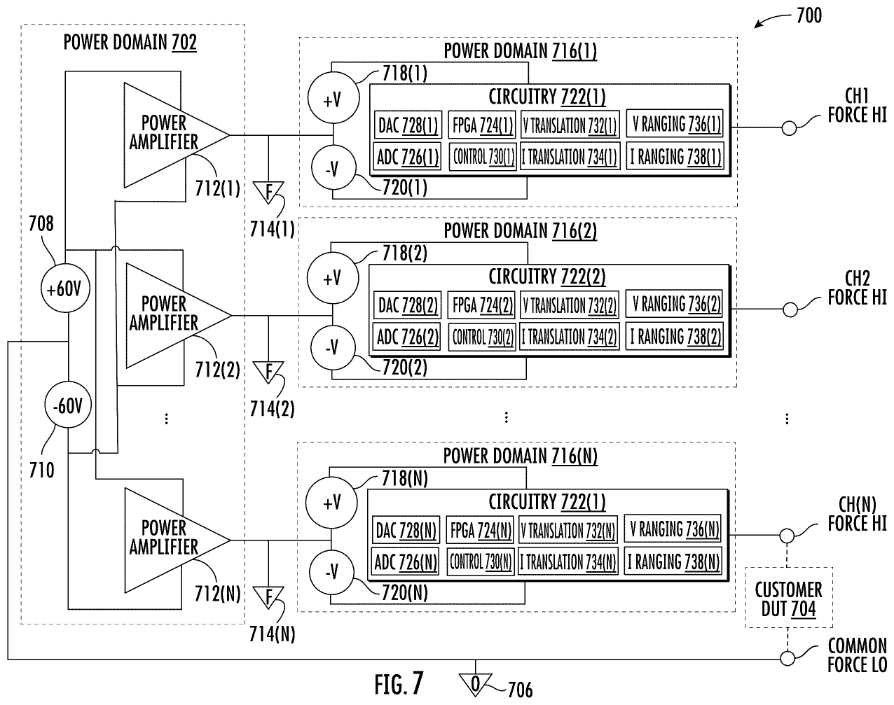

FIG. 7 is a diagram showing a system 700 with multiple channels, each channel having its own isolated power domain. As illustrated in FIG. 7, a first isolated power domain 702 is coupled to any number of secondary isolated power domains 716(1)-(n). Reference to and description of any secondary isolated power domain 716(including any components thereof) can apply to any of the secondary isolated power domains 716(1)-(n) (including any components thereof). The number of secondary isolated power domains 716 depends on the number of channels supported by the system 700.

The first isolated power domain 702 includes power supplies 708, 710 similar to the power supplies 608, 610 of the first power domain 602 of FIG. 6. Similarly, the power supplies 708, 710 are coupled to ground 706 and the output Common Force LO. The first isolated power domain 702 has any number of power amplifiers 712(1)-(n), corresponding to the number of secondary isolated power domains 716. That is, the first isolated power domain 702 has a power amplifier 712 for each secondary isolated power domain 716, and the power amplifier 712 produces the output of the power domain 702. Reference to and description of any power amplifier 712 can apply to any of the power amplifier 712(1)-(n). Each power amplifier 712 of the first isolated power domain 702 is coupled to one of the secondary isolated power domain 716. Each power amplifier 712 of the first isolated power domain 702 is coupled to each of the power supplies 708, 710.

As illustrated in FIG. 7, each secondary isolated power domains 716 has their own power supplies 718, 720 coupled to a floating ground 714. Each of the secondary isolated power domains 716 further includes circuitry 722 that can include but is not limited to a floating FPGA 724, any ADCs 726 and DACs 728, control circuitry 730, sense circuitry, and all voltage and current range controls 736, 738. The circuitry 722 of each secondary isolated power domain 716 is configured to interact with the DUT 704, and the circuitry 722 can include circuits needed to perform test and measurement operations on the DUT 704. Each of the secondary isolated power domains 716 in turn is coupled to a corresponding output CH1-CH(N) Force HI.

In a multichannel design with a common Force LO, such as the system 700 shown in FIG. 7, some design simplifications can be made by sharing some supply domains between channels. FIG. 7 illustrates how the power amplifiers 712, all sharing a single common Force LO, can also share power supplies 708, 710 (also referred to as supply rails). However, each channel has its own Force HI, meaning that each channel needs an independent power supply domain (e.g., one of secondary isolated power domains 716) and thus either its own transformer or its own isolated set of windings on the power amplifier transformer, both of which increase the required cost and area as the number of channels increase. Because each secondary isolated domain 716 requires multiple watts of isolated power, miniaturization is difficult.

The present disclosure herein also described a system architecture that addresses the cost and area requirements discussed with regards to the system 700 of FIG. 7.

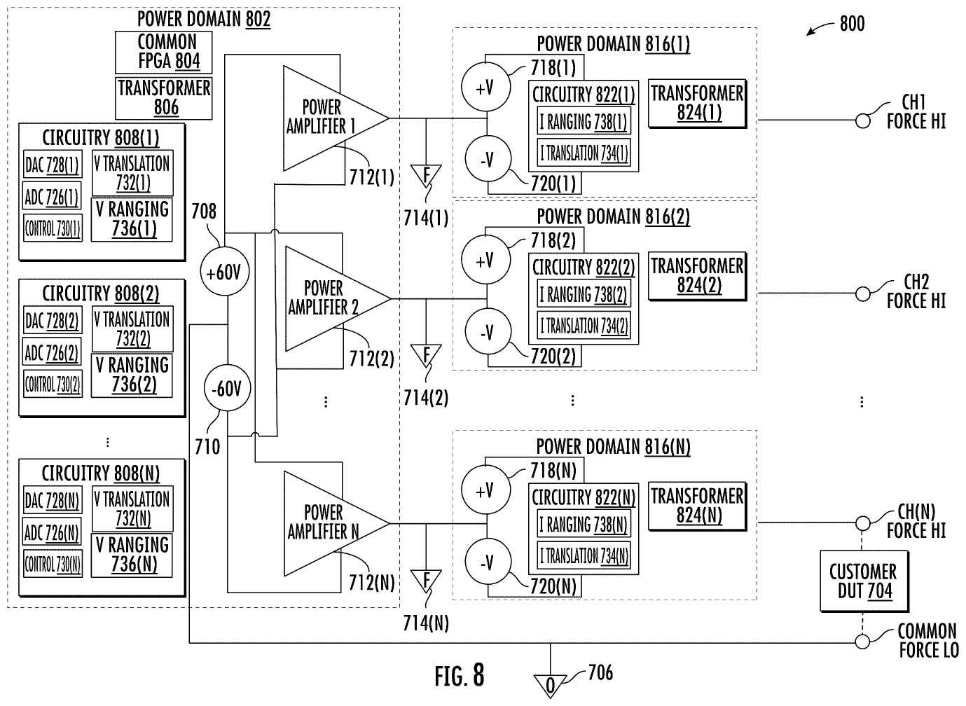

FIG. 8 is a diagram showing a system 800 having a primary power domain and multiple secondary power domains. Like with the system architecture shown in FIG. 7, the system 800 of FIG. 8 includes a first isolated power domain 802. The first isolated power domain 802, which also may be referred to herein as a primary power domain, is coupled to any number of secondary isolated power domains 816. Reference to and description of any secondary isolated power domain 816 (including any components thereof) can apply to any of the secondary isolated power domains 816(1)-(n) (including any components thereof). The number of secondary isolated power domains 816 depends on the number of channels supported by the system 800.

The first isolated power domain 802 includes power supplies 708, 710 similar to the power supplies 708, 710 of the first isolated power domain 702 of FIG. 7. Similarly, the power supplies 708, 710 are coupled to ground 706 and the output Common Force LO. In some examples, the ground 706 is a floating ground relative to Earth ground or relative to a ground provided by an external source. The first isolated power domain 802 has any number of power amplifiers 712(1)-(n) corresponding to the number of secondary isolated power domains 816. That is, the first isolated power domain 802 has a power amplifier 712 for each secondary isolated power domain 816. Each power amplifier 712 of the first isolated power domain 802 is coupled to one of the secondary isolated power domain 816. Each power amplifier 712 of the first isolated power domain 802 is coupled to each of the power supplies 708, 710.

Like with FIG. 7, FIG. 8 illustrates how the power amplifiers 712, all sharing a single common Force LO, can also share power supplies 708, 710 However, each channel has its own Force HI, meaning that each channel needs an independent power supply domain (e.g., one of secondary isolated power domains 816) and thus either its own transformer or its own isolated set of windings on the transformer. Each secondary isolated power domain 816 includes power supplies 718, 720 coupled to a floating ground 714 and to a transformer 824 for the respective secondary isolated power domain 816. In some examples, the floating ground 714 is floating relative to ground 706, Earth ground, and/or another source. The transformer 824 of each secondary isolated power domain 816 is coupled to the output of the respective power amplifier 712 of the first isolated power domain 802. The transformer 824 of each secondary isolated power domain 816 isolates and transforms the power from the first isolated power domain 802 to the amount of respective power needed for the secondary isolated power domain 816.

In FIG. 8, most circuits have been removed from the secondary isolated power domains 816 and moved to the common OGND domain as compared to the circuitry 722 of the secondary power domains 716 of FIG. 7. For example, circuits 726, 728, 730, 732, 736 have been moved from the secondary isolated power domains 816 and these circuits 726, 728, 730, 732, 736 are coupled to receive power from the first isolated power domain 802. Accordingly, as illustrated, the first isolated power domain 802 comprises circuitry 808, such as a common FPGA 804 configured to be used by circuitry 822 of each of the secondary isolated power domains 816. Instead of each secondary isolated power domain 816 having an FPGA like the FPGA 724 of the secondary isolated power domains 716 of FIG. 7, the system 800 has a common FPGA 804 powered by the first isolated power domain 802. The first isolated power domain 802 can also include circuitry 808 for each of the secondary isolated power domains 816, including but not limited to DACs 728, ADCs 726, control circuitry 730, voltage translation circuitry 732, and voltage ranging circuitry 736. Each of circuitry 808(1)-(n) correspond to a respective secondary isolated power domain 816, and are powered by the first isolated power domain 802. Each of the secondary isolated power domains 816 in turn is coupled to a corresponding channel output Force HI.

Correspondingly, each of the secondary isolated power domains 816 include circuitry 822, such as current ranging circuitry 738 and current translation circuitry 734. The circuitry 822 can include other current measurement-related circuitry. In some examples, the remaining circuitry 822 in the secondary power domains 816 has been optimized to consume little power (e.g., less than 100 mW for each secondary power domain 816) by: (1) using low-quiescent-current analog switches in circuitry 822 of the secondary isolated power domains 816 to handle current range switching (as opposed to comparators+FETs), (2) redesigning the current ranging selection mechanism in the circuitry 822 of the secondary isolated power domains 816 to reduce the number of unique switches required, (3) allowing the supply rails to supplement the current translation circuits 734 of the circuitry 822 of the secondary isolated power domains 816, and (4) using passive opto-isolators in the circuitry 822 of the secondary isolated power domains 816 for control signals not requiring fast response times. In some examples, low-Iq glue logic (i.e., logic gates that perform logic functions requiring low quiescent current as compared to a microprocessor, which requires much more power) is used to allow any number of current ranging signals crossing the isolation barrier between power domain 802 and 816 to control guard circuits (not illustrated) for low current leakage and allowing low current measurements and current ranging circuitry 738 of the circuitry 822 of the secondary isolated power domains 816.

In some examples, the first isolated power domain 802 includes a transformer 806, and the secondary isolated power domains 816 each include a transformer 824. The transformers 806, 822 are configured to isolate the first isolated power domain 802 from the secondary isolated power domain 816. In some examples, the transformers 824 for the secondary isolated power domains 816 includes a first winding (not illustrated) coupled to the respective power supplies 718, 720 and to the respective floating ground 714, and a second winding coupled to the respective power amplifier 712 and to ground 706. In some examples, the transformers 824 for the secondary isolated power domains 816 are a part of a single transformer, such as an octal transformer. The system 800 of FIG. 8 can use an octal transformer due to the low power requirements. In such examples, the system 800 can use a high-density octal transformer designed for isolated communication rather than power, which can be used in the system architecture of FIG. 8 due to the low power requirements. In such examples, to further reduce the required board space, all eight primaries in this octal transformer can be driven in parallel with a single source, as the power requirements are low and thus resistive losses are minimal. In other words, the system 800 does not require any closed loop control to adjust the output based on the power requirements as those power requirements of circuitry 822 of the secondary power domains 816 are sufficiently small. With this part and a single primary-side driver, a single octal transformer can produce eight secondary isolated power domains in approximately 1 square inch of board space.

Accordingly, the system architecture of FIG. 8 preserves benefits of the isolated power domains, though not all. The system architecture of FIG. 8 still has the capability to bias and control switches with power supplies (e.g., power supplies of power domains 816) above the power rails (e.g., power supplies of power domain 802), and still provides a true low-impedance ground. In some examples, the system architecture of FIG. 8 may have common-mode error on current measurements, but to reduce corresponding impact of common-mode error on current measurements, the system 800 can utilize a high common mode rejection ratio (CMRR) current translator circuit. Furthermore, the system 800 can performs simultaneous current and voltage measurements, and thereby can post-process the current measurement using some form of common mode offset calibration/compensation in firmware.

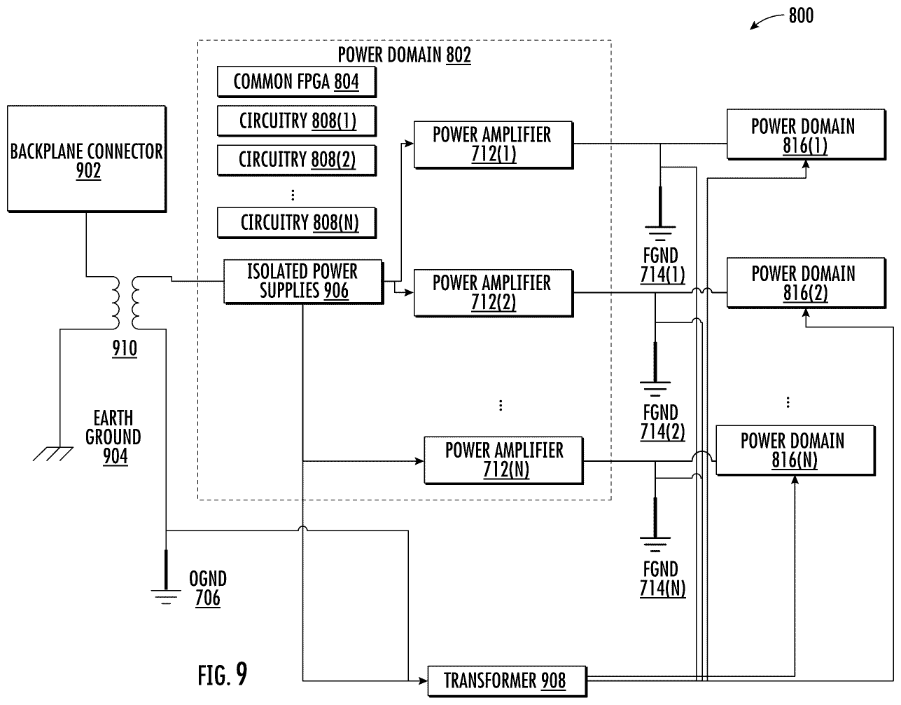

FIG. 9 is another diagram illustrating the system 800 of FIG. 8 coupled to a backplane connector, according to some examples. As illustrated in FIG. 9, the system 800 includes a first isolated power domain 802. The first isolated power domain 802 can be the same as the first isolated power domain 802 of FIG. 8, and accordingly, any description of the first isolated power domain 802 of FIG. 8 applies to the first isolated power domain 802 of FIG. 9.

The system 800 also includes multiple secondary isolated power domains 816(1)-(n). The secondary isolated power domains 816 can be the same as the secondary isolated power domains 816 of FIG. 8, and accordingly, any description of the secondary isolated power domains 816 of FIG. 8 applies to the secondary isolated power domains 816 of FIG. 9.

The system 800 also includes multiple floating grounds 714 for each of the secondary isolated power domains 816. The floating grounds 714 can be the same as the floating grounds 714 of FIG. 8, and accordingly, any description of the floating grounds 714 of FIG. 8 applies to the floating grounds 714 of FIG. 9.

Referring back to the first isolated power domain 802, like the first isolated power domain 802 of FIG. 8, the first isolated power domain 802 of FIG. 9 includes a common FPGA 804, and circuitry 808(1)-(n). As previously mentioned, circuitry 808 corresponds to an associated power domain 816. The circuitry 808 can be the same as the circuitry 808 of FIG. 8, and accordingly, any description of the circuitry 808 applies to the circuitry 808 of FIG. 9.

The first isolated power domain 802 also includes isolated power supplies 906. In some examples, the isolated power supplies 906 correspond to power supplies 708, 710 of FIG. 8, and accordingly any description of the power supplies 708, 710 applies to the isolated power supplies 906 of FIG. 9. Like with the power supplies 708, 710 of FIG. 8, the isolated power supplies 906 is coupled to each of the power amplifiers 712 of power domain 802.

The isolated power supplies 906 is also coupled to a transformer 908. In some examples, the transformer 908 is designed for isolated communication rather than power. In some examples, the transformer 908 is an octal transformer. In such example, all eight primaries of the transformer 908 can be driven in parallel with a single power source, and accordingly, the transformer 908 can produce up to eight isolated domains with a single component. In some examples, the transformer 908 can include the transformers 824 of FIG. 8. In such examples, the transformer 908 includes a first winding (not illustrated) coupled to the isolated power supplies 906, and a second winding (not illustrated) coupled to the power domains 816. In further examples, the first winding can include multiple windings coupled to the isolated power supplies 906, and correspondingly, the second winding of the transformer 908 can include multiple windings, each coupled to one of the secondary isolated power domains 816. In some examples, the transformer 908 can be coupled to ground 706 via the first winding of the transformer 908, and to any one of the floating grounds 714 via the second winding of the transformer 908.

The isolated power supplies 906 of the first isolated power domain 802 is also coupled to another transformer 910. The transformer 910 comprises a first winding coupled to a backplane connector 902 and to Earth ground 904 or another ground provided by a user. The backplane connector provides power and communication from an Earth-grounded mainframe. The transformer comprises a second winding coupled to the isolated power supplies 906 and to ground 706, which, as mentioned, can be a floating ground relative to Earth ground 904. The transformer 910, like transformer 908, can be designed for isolated power between the backplane connector 902 and the first isolated power domain 802.

The present disclosure describes how to handle multi-channel isolated power domains.

Application of the present disclosure to saves significant layout space and reduces the cost of the power supply circuitry for high density multichannel SMUs.

The present disclosure describes the architecture of secondary isolated power domains in conjunction with a first isolated power domain. By sharing elements between channels (e.g., FPGA 804) in the first isolated power domain 802, moving other elements from the secondary isolated power domains to the first isolated power domain (e.g., control circuitry 730, ADCs 726, voltage ranging circuits 736), and then redesigning and optimizing the remaining circuitry of the secondary isolated power domains, each secondary isolated power domains now only occupies approximately one square inch of board space and consumes less than 0.1 W of isolated power. As a result, the eight required isolated floating power supply domains can be generated using a single off-the-shelf pulse transformer.

In this disclosure, the singular forms “a,” “an,” and “the” include plural referents unless the context dictates otherwise. The term “or” is meant to be inclusive and means either, any, several, or all of the listed items. The terms “comprises,” “comprising,” “includes,” “including,” or other variations thereof, are intended to cover a non-exclusive inclusion such that a process, method, or product that comprises a list of elements does not necessarily include only those elements, but may include other elements not expressly listed or inherent to such a process, method, article, or apparatus. Relative terms, such as “about,” “approximately,” “substantially,” and “generally,” are used to indicate a possible variation of ±10% of a stated or understood value.

The aspects of the present disclosure are susceptible to various modifications and alternative forms. Specific aspects have been shown by way of example in the drawings and are described in detail herein. However, one should note that the examples disclosed herein are presented for the purposes of clarity of discussion and are not intended to limit the scope of the general concepts disclosed to the specific aspects described herein unless expressly limited. As such, the present disclosure is intended to cover all modifications, equivalents, and alternatives of the described aspects in light of the attached drawings and claims.

References in the specification to aspect, example, etc., indicate that the described item may include a particular feature, structure, or characteristic. However, every disclosed aspect may or may not necessarily include that particular feature, structure, or characteristic. Moreover, such phrases are not necessarily referring to the same aspect unless specifically noted. Further, when the discussion described a particular feature, structure, or characteristic in connection with a particular aspect, such feature, structure, or characteristic can be employed in connection with another disclosed aspect whether or not such feature is explicitly described in conjunction with such other disclosed aspect.

Aspects of the disclosure may operate on a particularly created hardware, on firmware, digital signal processors, or on a specially programmed general-purpose computer including a processor operating according to programmed instructions. The terms controller or processor as used herein include microprocessors, microcomputers, Application Specific Integrated Circuits (ASICs), cloud-based servers, and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid-state memory, Random Access Memory (RAM), etc. As will be appreciated by one of skill in the art, the functionality of the program modules may be combined or distributed as desired in various aspects. In addition, the functionality may exist in whole or in part in firmware or hardware equivalents such as integrated circuits, FPGA, and the like. Particular data structures may be used to implement more effectively one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that accessible by a computing device. By way of example, and not limitation, computer-readable media may comprise computer storage media and communication media.

Computer storage media means any medium that can store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can communicate computer-readable information. By way of example, and not limitation, communication media may include coaxial cables, fiber-optic cables, air, or any other media suitable for the communication of electrical, optical, Radio Frequency (RF), infrared, acoustic or other types of signals.

The disclosed aspects may be implemented, in some cases, in hardware, firmware, software, or any combination thereof. References made above to FPGAs and other integrated circuits such as voltage regulators, etc., may be replaced with any component that can perform the same functions. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Also, when reference is made in this application to a method having two or more defined steps or operations, the defined steps or operations can be carried out in any order or simultaneously, unless the context excludes those possibilities.

Although specific aspects of the disclosure have been illustrated and described for purposes of illustration, it will be understood that various modifications may be made without departing from the spirit and scope of the disclosure. Accordingly, the disclosure should not be limited except as by the appended claims.

### Examples

Illustrative examples of the disclosed technologies are provided below. An embodiment of the technologies may include one or more, and any combination of, the examples described below.

Example 1 is a system, including: a primary power domain having: a first set of power supplies; a first ground; a first set of measurement devices coupled to the first ground and is configured to be powered by at least one of the first set of power supplies; and a second set of measurement devices coupled to the first ground and is configured to be powered by at least one of the first set of power supplies; at least two isolated secondary power domains, each coupled to the primary power domain, each of the at least two isolated secondary power domains having: a second set of power supplies; a second ground different from the first ground; a transformer coupled to the primary power domain, to the second set of power supplies, and to the second ground; and a third set of measurement devices coupled to the second ground and are configured to be powered by at least one of the second set of power supplies; and where the first set of measurement devices is associated with a first of the at least two isolated secondary power domains and the second set of measurement devices is associated to a second of the at least two isolated secondary power domains.

Example 2 is the system of Example 1, where the first ground and the second ground are floating.

Example 3 is the system of Example 1 or Example 2, where the second ground is floating relative to the first ground.

Example 4 is the system of any one of Example 1-3, where the first ground is floating relative to Earth ground.

Example 5 is the system of any one of Example 1-4, where the second ground of each secondary power domain is coupled between the primary power domain and the respective isolated secondary power domain and is separate and isolated from the second ground of each other secondary power domain.

Example 6 is the system of any one of Example 1-5, where the at least two isolated secondary power domains comprise a first winding of the transformer, and the primary power domain may include the second winding of the transformer.

Example 7 is the system of any one of Example 1-6, where the third set of measurements in each of the at least two isolated secondary power domains is configured to consume less power than the first set of measurement devices or the second set of measurement devices.

Example 8 is the system of any one of Example 1-7, where each of the at least two isolated secondary power domains is different from the primary power domain.

Example 9 is the system of any one of Example 1-8, where at least one of the at least two isolated secondary power domains powers a source measure unit (SMU) channel.

Example 10 is the system of any one of Example 1-9, where the primary power domain may include a plurality of power amplifiers, each configured to provide power to one of the at least two isolated secondary power domains.

Example 11 is the system of any one of Example 1-10, where the primary power domain may include a field programmable gate array configured to process data for each third set of measurement devices of the at least two isolated secondary power domains.

Example 12 is the system of any one of Example 1-11, where the first set of measurement devices comprise at least one of analog-to-digital converters, digital-to-analogic converters, and voltage sensors.

Example 13 is the system of any one of Example 1-12, where the third set of measurement devices may include a current sensor.

Example 14 is the system of any one of Example 1-13, where the transformer is configured to isolate the primary power domain from the at least two isolated secondary power domains.

Example 15 is the system of any one of Example 1-14, where each of the secondary power domains may include an output node, and where a device under test is configured to be coupled to the output node and the first ground.

Example 16 is a system including: a first circuit having: a first set of power supplies; a first ground; a first set of measurement devices coupled to the first ground and is configured to be powered by at least one of the first set of power supplies; and a second set of measurement devices coupled to the first ground and is configured to be powered by at least one of the first set of power supplies; and a second and third isolated circuit, each coupled to the first circuit, each of the second and third isolated circuits having: a second set of power supplies; a second ground different from the first ground; a transformer coupled to the first circuit, the second set of power supplies, and the second ground; and a third set of measurement devices coupled to the second ground and are configured to be powered by at least one of the second set of power supplies; and where the first set of measurement devices is associated with the second isolated circuit and the second set of measurement devices is associated to the third isolated circuit.

Example 17 is the system of Example 16, where the first ground and the second ground are floating.

Example 18 is the system of Example 16 or Example 17, where the second ground is floating relative to the first ground.

Example 19 is the system of any one of Example 16-18, where the first ground is floating relative to Earth ground.

Example 20 is the system of any one of Example 16-19, where the second ground of the second isolated circuit is separate and isolated from the second ground of the third isolated circuit.

The previously described versions of the disclosed subject matter have many advantages that were either described or would be apparent to a person of ordinary skill. Even so, these advantages or features are not required in all versions of the disclosed apparatus, systems, or methods.

Additionally, this written description makes reference to particular features. It is to be understood that the disclosure in this specification includes all possible combinations of those particular features. Where a particular feature is disclosed in the context of a particular aspect or example, that feature can also be used, to the extent possible, in the context of other aspects and examples.

Also, when reference is made in this application to a method having two or more defined steps or operations, the defined steps or operations can be carried out in any order or simultaneously, unless the context excludes those possibilities.

Although specific examples of the invention have been illustrated and described for purposes of illustration, it will be understood that various modifications may be made without departing from the spirit and scope of the invention. Accordingly, the invention should not be limited except as by the appended claims.

What is claimed is:

1. A system, comprising:
a primary power domain having:
a first set of power supplies;
a first ground;
a first set of measurement devices coupled to the first ground and is configured to be powered by at least one of the first set of power supplies; and
a second set of measurement devices coupled to the first ground and is configured to be powered by at least one of the first set of power supplies;
at least two isolated secondary power domains, each coupled to the primary power domain, each of the at least two isolated secondary power domains having:
a second set of power supplies;
a second ground different from the first ground;
a transformer coupled to the primary power domain, to the second set of power supplies, and to the second ground; and
a third set of measurement devices coupled to the second ground and are configured to be powered by at least one of the second set of power supplies; and
wherein the first set of measurement devices is associated with a first of the at least two isolated secondary power domains and the second set of measurement devices is associated to a second of the at least two isolated secondary power domains.

2. The system of claim 1, wherein the first ground and the second ground are floating.

3. The system of claim 2, wherein the second ground is floating relative to the first ground.

4. The system of claim 2, wherein the first ground is floating relative to Earth ground.

5. The system of claim 1, wherein the second ground of each secondary power domain is coupled between the primary power domain and the respective isolated secondary power domain and is separate and isolated from the second ground of each other secondary power domain.

6. The system of claim 1, wherein the at least two isolated secondary power domains comprise a first winding of the transformer, and the primary power domain comprises a second winding of the transformer.

7. The system of claim 1, wherein the third set of measurements in each of the at least two isolated secondary power domains is configured to consume less power than the first set of measurement devices or the second set of measurement devices.

8. The system of claim 1, wherein each of the at least two isolated secondary power domains is different from the primary power domain.

9. The system of claim 1, wherein at least one of the at least two isolated secondary power domains powers a source measure unit (SMU) channel.

10. The system of claim 1, wherein the primary power domain comprises a plurality of power amplifiers, each configured to provide power to one of the at least two isolated secondary power domains.

11. The system of claim 1, wherein the primary power domain comprises a field programmable gate array configured to process data for each third set of measurement devices of the at least two isolated secondary power domains.

12. The system of claim 1, wherein the first set of measurement devices comprise at least one of analog-to-digital converters, digital-to-analogic converters, and voltage sensors.

13. The system of claim 1, wherein the third set of measurement devices comprises a current sensor.

14. The system of claim 1, wherein the transformer is configured to isolate the primary power domain from the at least two isolated secondary power domains.

15. The system of claim 1, wherein each of the isolated secondary power domains comprises an output node, and wherein a device under test is configured to be coupled to the output node and the first ground.

16. A system comprising:
a first circuit having:
a first set of power supplies;
a first ground;
a first set of measurement devices coupled to the first ground and is configured to be powered by at least one of the first set of power supplies; and
a second set of measurement devices coupled to the first ground and is configured to be powered by at least one of the first set of power supplies; and
a second and third isolated circuit, each coupled to the first circuit, each of the second and third isolated circuits having:
a second set of power supplies;
a second ground different from the first ground;
a transformer coupled to the first circuit, the second set of power supplies, and the second ground; and
a third set of measurement devices coupled to the second ground and are configured to be powered by at least one of the second set of power supplies; and
wherein the first set of measurement devices is associated with the second isolated circuit and the second set of measurement devices is associated to the third isolated circuit.

17. The system of claim 16, wherein the first ground and the second ground are floating.

18. The system of claim 17, wherein the second ground is floating relative to the first ground.

19. The system of claim 17, wherein the first ground is floating relative to Earth ground.

20. The system of claim 16, wherein the second ground of the second isolated circuit is separate and isolated from the second ground of the third isolated circuit.
